(19) United States
(12) Patent Application Publication
(10) Pub. No.: US 2008/0174010 A1
(43) Pub. Date: Jul. 24, 2008

(54) MEMS ELEMENT FABRICATION METHOD AND MEMS ELEMENT

(75) Inventors: Kazuhiro Suzuki, Tokyo (JP); Seth Hollar, Tokyo (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/847,501

(22) Filed: Aug. 30, 2007

(30) Foreign Application Priority Data
Sep. 27, 2006 (JP) 2006-263118

(51) Int. Cl. H01L 21/44; H01L 23/52

(52) U.S. Cl. 257/735; 438/611; 257/E21.476; 257/E23.141

(57) ABSTRACT

A method of fabricating a MEMS element includes forming a MEMS element by forming a circuit layer on an element layer of an SOI substrate that is formed by laminating on a substrate, a first insulation layer and the element layer, and forming a second insulation layer including a conductive beam electrically connected to the circuit layer on the element layer on which the circuit layer is not formed; first removing a part of the second insulation layer and a part of the element layer by anisotropic etching; second removing by forming an opening reaching to the element layer in the second insulation layer, and removing the element layer located below the conductive beam through the opening by isotropic etching; and third removing by removing the second insulation layer to expose the conductive beam, and removing the first insulation layer located below the conductive beam.

### CROSS-REFERENCE TO RELATED APPLICATIONS

This application is based upon and claims the benefit of priority from the prior Japanese Patent Application No. 2006-263118, filed on Sep. 27, 2006; the entire contents of which are incorporated herein by reference.

### BACKGROUND OF THE INVENTION

1. Field of the Invention

The present invention relates to a MEMS element fabrication method for fabricating a microelectromechanical system (MEMS) on a substrate and the MEMS element.

2. Description of the Related Art

A microelectromechanical system (MEMS) is typically a semiconductor element fabricated using any known semiconductor processing technology. MEMS elements have enhanced electromagnetic sensing capabilities when compared with larger semiconductor elements. Further, MEMS elements can be batch fabricated, enabling low-cost fabrication.

Surface micromachining and bulk micromachining are two known fabrication methods of MEMS elements. In surface micromachining, the MEMS elements are formed on a silicon substrate by a sequence of three processes, namely, deposition, etching, and lithography. By repeating the three processes, a plurality of structural layers can be formed on the silicon substrate to fabricate a MEMS element. Surface micromachining is generally used for depositing films of the dimension as thin as two or three microns for forming movable hinges or beams. When used in a two-dimensional semiconductor manufacturing process, the movable hinges and beams enable fabrication of a three-dimensional MEMS element (refer to JP-A 2003-260699 (KOKAI) and U.S. Pat. No. 6,755,982).

MEMS elements can have enhanced electrostatic sensing capabilities and actuation performance if the structural layers can be made thicker and more rigid. Bulk micromachining is deployed for obtaining thicker structural layers. In bulk micromachining, a MEMS structure is obtained by etching the entire substrate or a part of the substrate. It has become possible to obtain MEMS element of an aspect ratio in the range of several hundred microns with the advent of silicon deep reactive ion etching (DRIE) technique.

The benefits of both the processes can ideally be reaped by combining surface micromachining and bulk micromachining. Surface micromachining can be used for fabricating a movable hinge or beam, enabling out-of-plane actuations. On the other hand, bulk micromachining can be used for fabricating structures with enhanced actuation performance or electromagnetic sensing capabilities.

There is a manufacturing technology available for combining the MEMS process with a complementary metal oxide conductor (CMOS) process, thereby integrating micromachined elements with circuits on the same substrate. The advantages of such a manufacturing technology are cost-effectiveness by way of reduction of the number of assembling processes and reduction in product size, and enhancement of performance by way of enhancement of sensitivity.

However, in surface micromachining, if the thickness of the layer formed is more than allowable limits or if the number of layers is far too many, the topography of the wafer surface after deposition of the structural layers will vary, affecting the resolution of the next layer. The impact is even greater particularly when high resolution is sought. A thick photoresist would be required to counter the topographical variation of the wafer surface, which would have lead to increased circuit size.

When fabricating MEMS elements using surface micromachining, the topography of the surface limits the line width required for the next layer. Consequently, it becomes difficult to micromachine the next layer on top of the surface that has been subjected to bulk micromachining. Therefore, further deposition on a thin film would be difficult during bulk micromachining. Further, it is generally difficult to subject perform deposition on a thin film after it has been subjected to bulk micromachining. Consequently, such MEMS elements cannot be used as hinges or beams, their functions essentially limited to in-plane actuations.

Further, the following problem is encountered when combining the MEMS process with the CMOS process. The CMOS process is a technically established process that generally requires 30 to 100 masks. On the other hand, the MEMS process is not as technically established as the CMOS process and normally requires less than 20 masks. The cost of modifying the CMOS process for designing a MEMS trial piece is normally huge. Therefore, most researchers and engineers prefer to carry a out MEMS process after the wafer is fabricated using the CMOS process. However, the CMOS chip is heat-sensitive, unable to withstand a temperature of 300° C. or greater, necessitating the MEMS process on a CMOS wafer to be carried out under low temperatures.

### SUMMARY OF THE INVENTION

According to one aspect of the present invention, a method of fabricating a MEMS element includes forming a MEMS element by forming a circuit layer on an element layer of an SOI substrate that is formed by laminating on a substrate, a first insulation layer and the element layer, and forming a second insulation layer including a conductive beam electrically connected to the circuit layer on the element layer on which the circuit layer is not formed; first removing a part of the second insulation layer and a part of the element layer by anisotropic etching; second removing by forming an opening reaching to the element layer in the second insulation layer, and removing the element layer located below the conductive beam through the opening by isotropic etching; and third removing by removing the second insulation layer to expose the conductive beam, and removing the first insulation layer located below the conductive beam.

According to another aspect of the present invention, a MEMS element includes a substrate; a first element layer including a circuit layer and a second element layer formed on the substrate; and a conductive beam that electrically connects the first element layer and the second element layer, wherein the conductive beam and the second element layer are separated from the substrate and are capable of mechanical actuation.

### BRIEF DESCRIPTION OF THE DRAWINGS

FIG. 1 is a top view of a substrate assembly according to an embodiment of the present invention obtained after an SOI wafer is subjected to a CMOS process;

FIG. 2A is a cross-sectional view of the substrate assembly along a viewline A-A shown in FIG. 1;

FIG. 2B is a cross-sectional view of the substrate assembly along a viewline B-B shown in FIG. 1;

FIG. 3 is a flowchart of the processes in fabrication of the MEMS element after the CMOS process;

FIG. 4A is a cross-sectional view of the substrate assembly along the viewline A-A shown in FIG. 1 after formation of a second mask layer;

FIG. 4B is a cross-sectional view of the substrate assembly along the viewline B-B shown in FIG. 1 after formation of the second mask layer;

FIG. 5A is a cross-sectional view of the substrate assembly along the viewline A-A shown in FIG. 1 after removal of an insulation layer by etching;

FIG. 5B is a cross-sectional view of the substrate assembly along the viewline B-B shown in FIG. 1 after removal of the insulation layer by etching;

FIG. 6A is a cross-sectional view of the substrate assembly along the viewline A-A shown in FIG. 1 after removal of a portion of a first element layer that corresponds to an unetched portion of the insulation layer;

FIG. 6B is a cross-sectional view of the substrate assembly along the viewline B-B shown in FIG. 1 after removal of a portion of a first element layer that corresponds to the unetched portion of the insulation layer;

FIG. 7A is a cross-sectional view of the substrate assembly along the viewline A-A shown in FIG. 1 after removal of a second mask layer;

FIG. 7B is a cross-sectional view of the substrate assembly along the viewline B-B shown in FIG. 1 after removal of the second mask layer;

FIG. 8A is a cross-sectional view of the substrate assembly along the viewline A-A shown in FIG. 1 after formation of a third mask layer;

FIG. 8B is a cross-sectional view of the substrate assembly along the viewline B-B shown in FIG. 1 after formation of the third mask layer;

FIG. 9A is a cross-sectional view of the substrate assembly along the viewline A-A shown in FIG. 1 after removal of the insulation layer below a resist window by etching;

FIG. 9B is a cross-sectional view of the substrate assembly along the viewline B-B shown in FIG. 1 after removal of the insulation layer below the resist window by etching;

FIG. 10A is a cross-sectional view of the substrate assembly along the viewline A-A shown in FIG. 1 after removal of a third element layer by etching;

FIG. 10B is a cross-sectional view of the substrate assembly along the viewline B-B shown in FIG. 1 after removal of the third element layer by etching;

FIG. 11A is a cross-sectional view of the substrate assembly along the viewline A-A shown in FIG. 1 after removal of the third mask layer;

FIG. 11B is a cross-sectional view of the substrate assembly along the viewline B-B shown in FIG. 1 after removal of the third mask layer;

FIG. 12A is a cross-sectional view of the substrate assembly along the viewline A-A shown in FIG. 1 after removal of the insulation layer, insulation trenches, and the buried silicon oxide (BOX) layer by release etching;

FIG. 12B is a cross-sectional view of the substrate assembly along the viewline B-B shown in FIG. 1 after removal of the insulation layer, the insulation trenches, and the buried silicon oxide (BOX) layer by release etching;

FIG. 13A is a cross-sectional view of the substrate assembly along the viewline A-A shown in FIG. 1 after removal of a first mask layer;

FIG. 13B is a cross-sectional view of the substrate assembly along the viewline B-B shown in FIG. 1 after removal of the first mask layer;

FIG. 14 is a schematic view showing a CAD design of a pin hinge;

FIG. 15 is a schematic view showing the pin hinge in its finished form;

FIG. 16 is a schematic view showing the pin hinge with its right side at an angle with respect to its left side;

FIG. 17 is a CAD design of a torsional hinge;

FIG. 18 is a schematic view showing the torsional hinge in its finished form; and

FIG. 19 is a schematic view showing the torsional hinge with its central portion twisted with respect to its end portions.

### DETAILED DESCRIPTION OF THE INVENTION

Exemplary embodiments of the MEMS element fabrication method and the MEMS element are described below with reference to the accompanying drawings.

The MEMS element fabrication method and the MEMS element according to an embodiment is a method that enables integration of a circuit and a three-dimensional MEMS structure by a simple monolithic process. An existing element in the CMOS circuit is used for fabricating the MEMS structure in this method. The number of processes the MEMS structure is subjected to is reduced to a great extent, resulting in cost reduction.

In the MEMS element fabrication method according to the embodiment, a CMOS element is first prepared for fabricating a Silicon on Insulator (SOI) wafer with components of the MEMS element formed thereon. The principal processes for SOI wafer fabrication are described below. A buried silicon oxide (BOX, buried oxide film) layer 109 and an element layer 105 are laminated on a substrate 108. A CMOS circuit 104 is formed on a part of the element layer 105 and an insulation layer 101 is laminated on the element layer 105. A first thin conductive layer 102 that is electrically connected to the CMOS circuit 104 is formed using the CMOS process in the insulation layer 101 covering the portion of the element layer 105 devoid of the CMOS circuit 104.

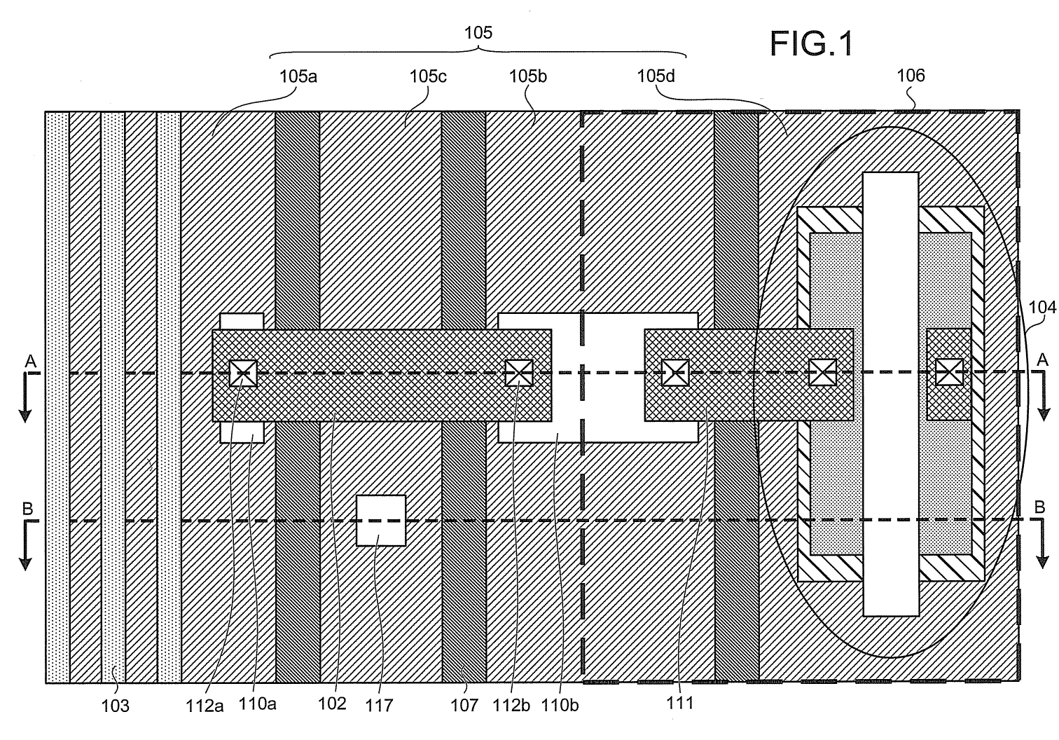

FIG. 1 is a top view of a silicon substrate which has been subjected to a standard CMOS process and which has formed thereon the structural components of the MEMS element. The silicon substrate in the present example is 500 microns thick. For the sake of simplification, the insulation layer 101 (described later) on the topmost surface of the substrate is not shown in FIG. 1 but the boundaries of a first mask layer 106 (described later) on the topmost layer of the substrate is shown by a dashed line. A resist window 117 (described later) of a resist mask 110 (described later), which is not present at the present stage, is also shown in FIG. 1.

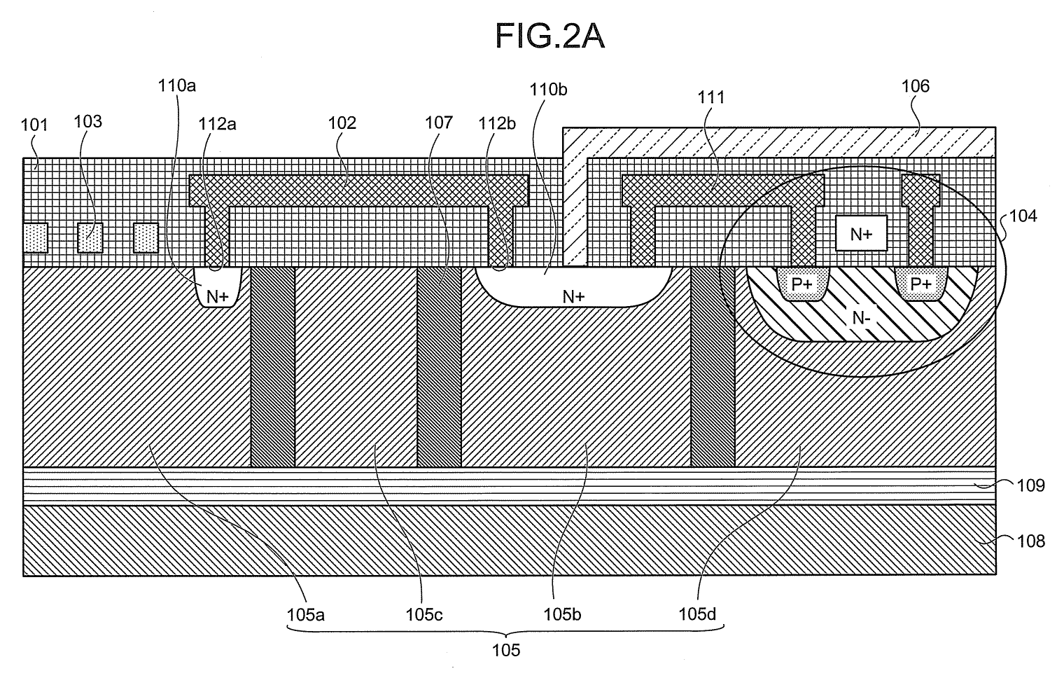

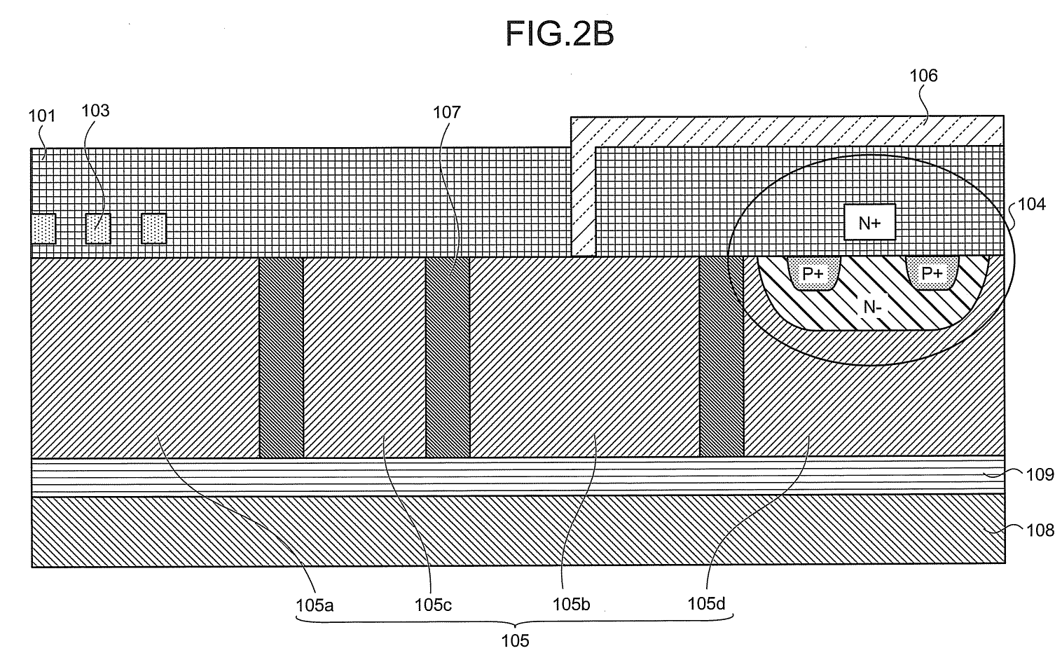

Sections along viewlines A-A and B-B of FIG. 1 are taken for explaining the embodiment. FIGS. 2A and 2B are cross-sectional views along the viewlines A-A and B-B, respectively, shown in FIG. 1, both views showing a substrate assembly after the standard CMOS processing and formation of the components of the MEMS element.

In FIGS. 2A and 2B, the MEMS element is fabricated to the left side and the central portion of the substrate section. Particularly, DRIE etching (anisotropic etching) is performed on the left side and an isotropic etching is performed in the central portion. To explain the compatibility of the MEMS element with the CMOS circuit, the CMOS circuit that includes a transistor is shown to the right of the central portion of the substrate section.

As shown in FIGS. 1, 2A, and 2B, the substrate assembly according to the embodiment includes the substrate 108 with the buried silicon oxide (BOX) layer 109, the element layer 105, and the insulation layer 101 formed sequentially thereon. More specifically, the substrate assembly according to the embodiment includes the first thin conductive layer 102, a second thin conductive layer 103, the CMOS circuit 104, the first mask layer 106, insulation trenches 107, the substrate 108, a first N-type region 110a, a second N-type region 110b, a metallic interconnect 111, a first contact portion 112a, a second contact portion 112b, an ion injection layer (not shown), and a field oxide layer (not shown).

The insulation layer 101 is made of an insulating material, generally silicon dioxide, and protects the wafer surface. The first thin conductive layer 102 is made of aluminum sandwiched between titanium nitride, and is electrically connected to the CMOS circuit 104. The first thin conductive layer 102 forms metallic beams of the MEMS element. The second thin conductive layer 103 is a polysilicon gate in the CMOS process. The second thin conductive layer 103 serves as a mask for the layers below it in a second etching process described later. The CMOS circuit 104 is an electronic circuit formed by the CMOS process and includes the transistor.

The element layer 105 is a portion in which an actual CMOS element is formed in the substrate, and is a silicon layer, also called an active layer. The element layer 105 includes a first element layer 105a, a second element layer 105b, a third element layer 105c, and a fourth element layer 105d. The element layer 105 is seven microns thick in the present example. The portion of the first element layer 105a that is retained after it is subjected to the second etching process and a portion of the second element layer 105b together form a portion of the MEMS element. The third element layer 105c is completely removed in a fourth etching process described later. The fourth element layer 105d is the portion that includes the CMOS circuit 104. The second element layer 105b and the fourth element layer 105d are not removed at all by the etching process described later.

The first mask layer 106 covers the entire CMOS circuit 104 and protects the CMOS circuit 104 during a release etching process described later, and is formed inside the portion delineated by the dashed line shown in FIG. 1. This mask is not necessary when the CMOS circuit 104 is not likely to be affected by the release etching process.

The insulation trenches 107 separate the element layer 105 into the four parts, namely, the first element layer 105a, the second element layer 105b, the third element layer 105c, and the fourth element layer 105d. The insulating material used in the present example is silicon dioxide. The insulation trenches 107 are formed by etching the element layer 105 from the inside and filling the trench with oxygen. The substrate 108 is monocrystalline silicon devoid of the CMOS element. The buried silicon oxide (BOX) layer 109 is formed of usually made of silicon oxide and insulates the element layer 105 and the substrate 108. The buried silicon oxide (BOX) layer 109 is two microns thick in the present example.

The first N-type region 110a and the second N-type region 110b are formed of N-type silicon by phosphorous ion injection. A part of the first N-type region 110a and the second N-type region 110b form a part of the MEMS element. The metallic interconnect 111 has a structure similar to the first thin conductive layer 102 and connects the elements of the CMOS circuit. The first contact portion 112a is a region where one end of the first thin conductive layer 102 connects with the first N-type region 110a. The second contact portion 112b is a region where one end of the first thin conductive layer 102 connects with the second N-type region 110b.

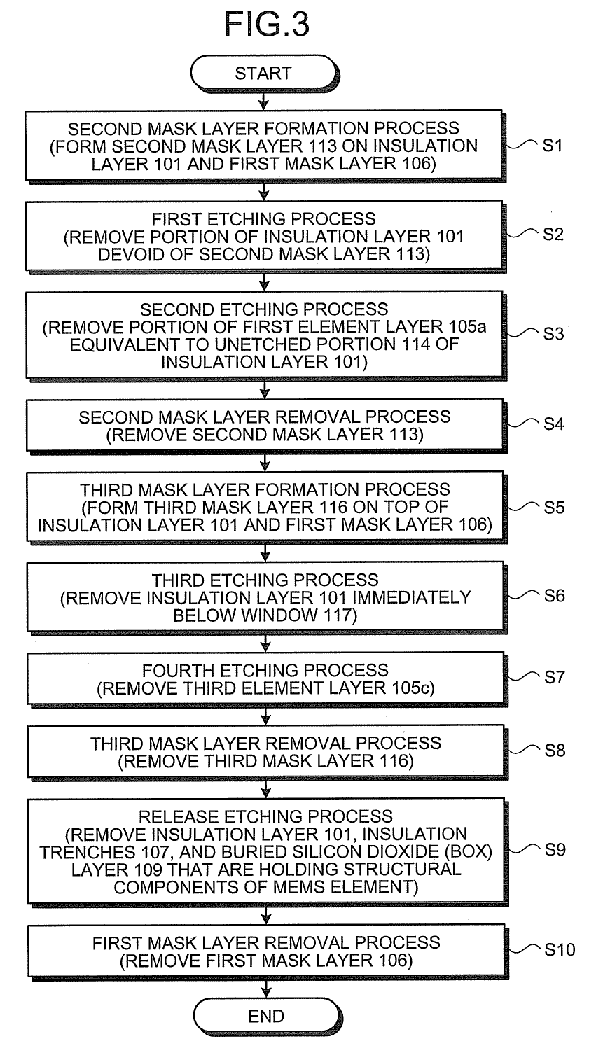

FIG. 3 is a flowchart of the processes in the fabrication of the MEMS element after the CMOS process.

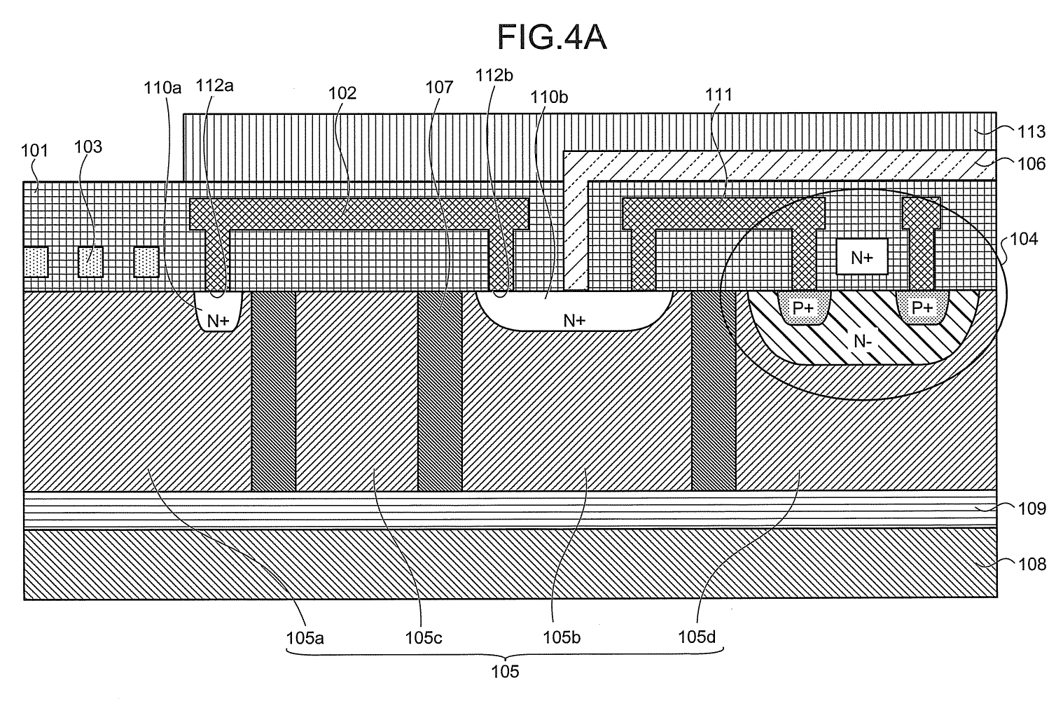

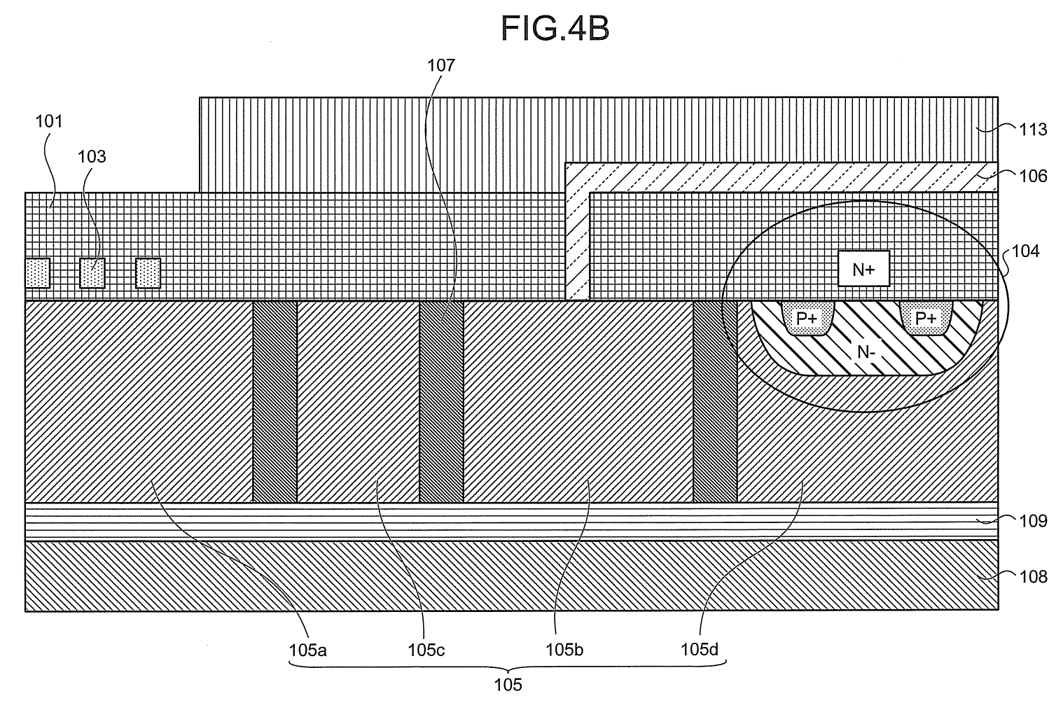

As shown in FIG. 3, at step S1, a second mask layer 113 is formed on top of the insulation layer 101 and the first mask layer 106, as shown in FIGS. 4A and 4B. A photoresist of a thickness of two to three microns is used in the second mask layer 113. By coating, exposing, and developing the photoresist in the required portions, the second mask layer 113 is formed in those portions. The second mask layer 113 is used for protecting the portion of the wafer below the second mask layer 113 between the first etching process and the second etching process described later. In the present embodiment, the beams from a portion of the first thin conductive layer 102, and a part of the circuit layer on the element layer 105 are already formed. The formation of the circuit layer on the element layer 105 and formation of the beams from the first thin conductive layer 102 however can also be included as processes that are performed prior to the second mask layer forming process.

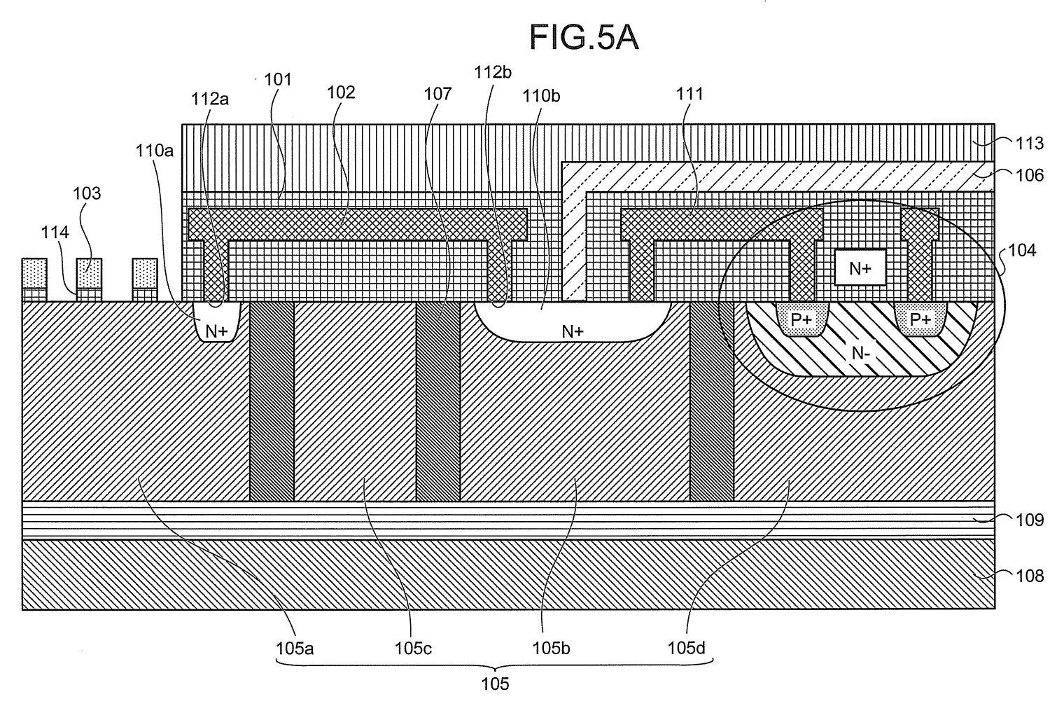

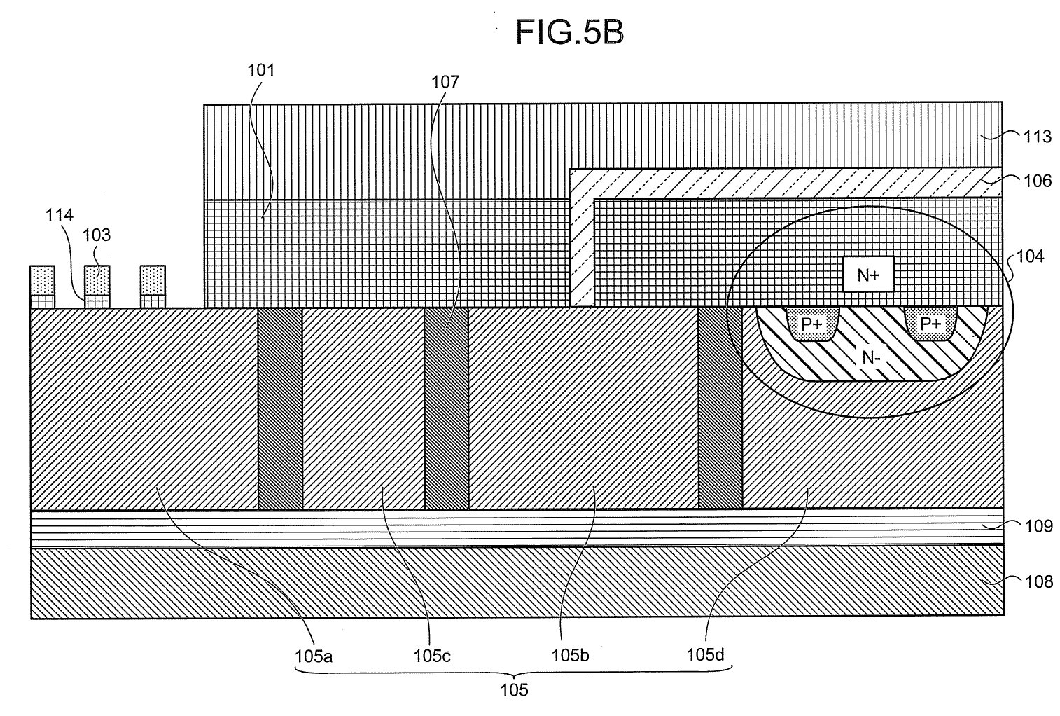

At step S2 in FIG. 3, the portion of the insulation layer 101 devoid of the second mask layer 113 is removed by etching (the first removal process), as shown in FIGS. 5A and 5B. The insulation layer 101 is normally two to three microns thick, and is etched by anisotropic etching. In the present example, reactive ion etching or deep reactive ion etching is used. This etching process does not remove the second thin conductive layer 103, and therefore, the insulation layer 101 below the second thin conductive layer 103 also remains intact. An unetched portion 114 of the insulation layer 101 serves as a mask for the first element layer 105a during the second etching process.

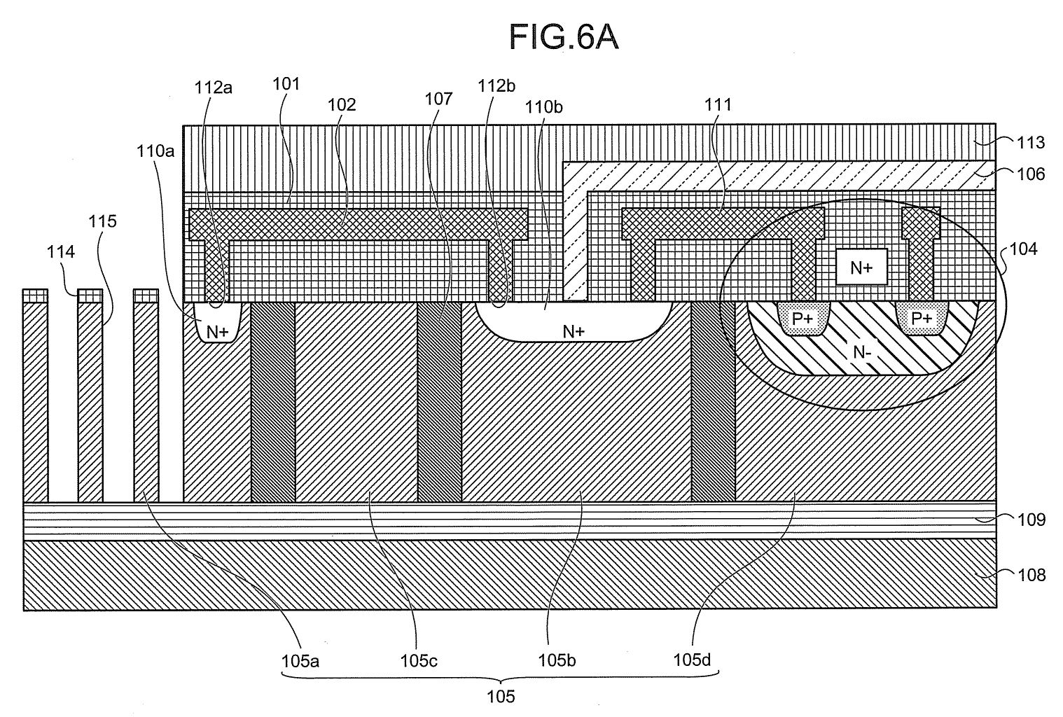

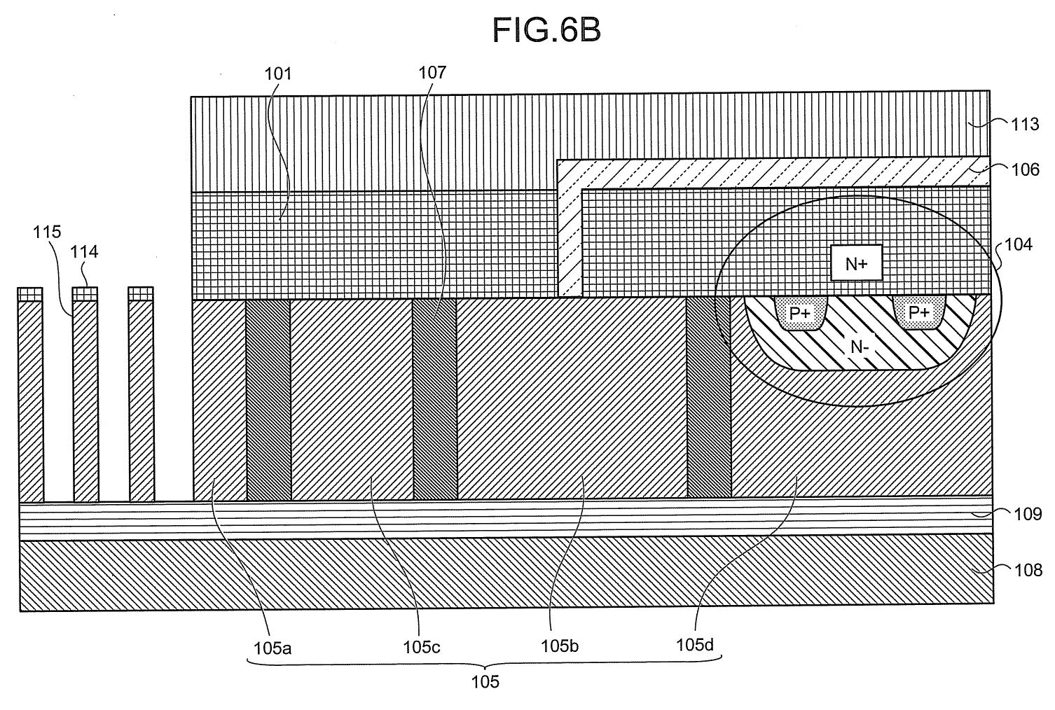

At step S3, a portion of the first element layer 105a equivalent to the unetched portion 114 of the insulation layer 101 is removed by etching (the first removal process), as shown in FIGS. 6A and 6B. The relevant portion of the first element layer 105a is etched by anisotropic etching. As an SOI wafer is used in the present embodiment, a silicon etching that stops at the buried silicon oxide (BOX) layer 109 can be used. This etching process also removes the second thin conductive layer 103. However, the unetched portion 114 of the insulation layer 101 and an unetched portion 115 of the first element layer 105a remain intact.

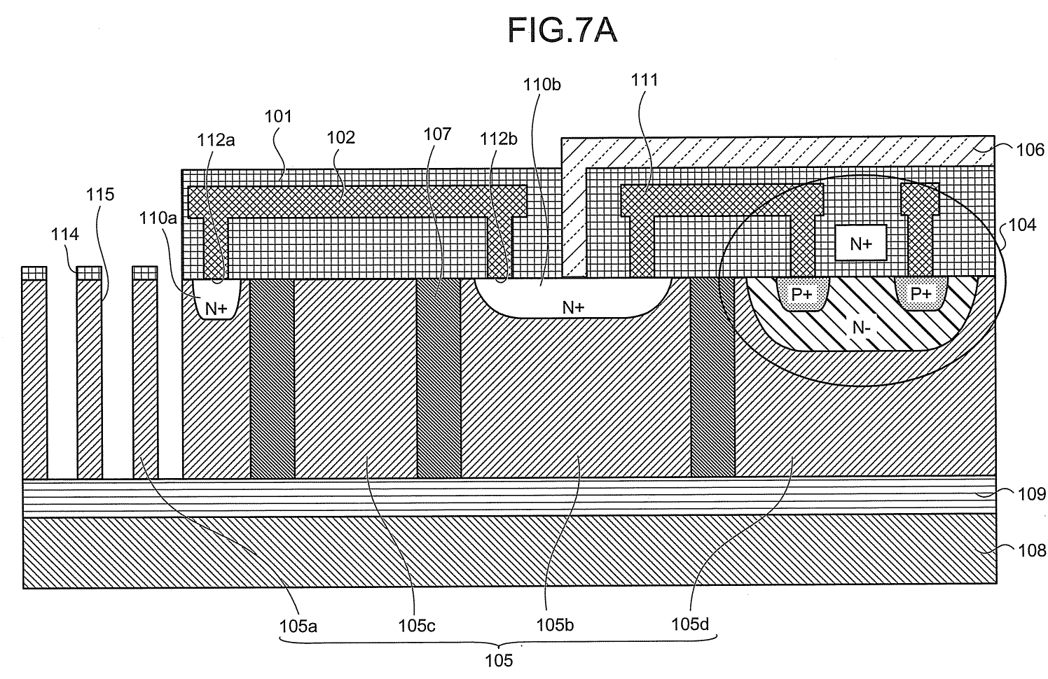

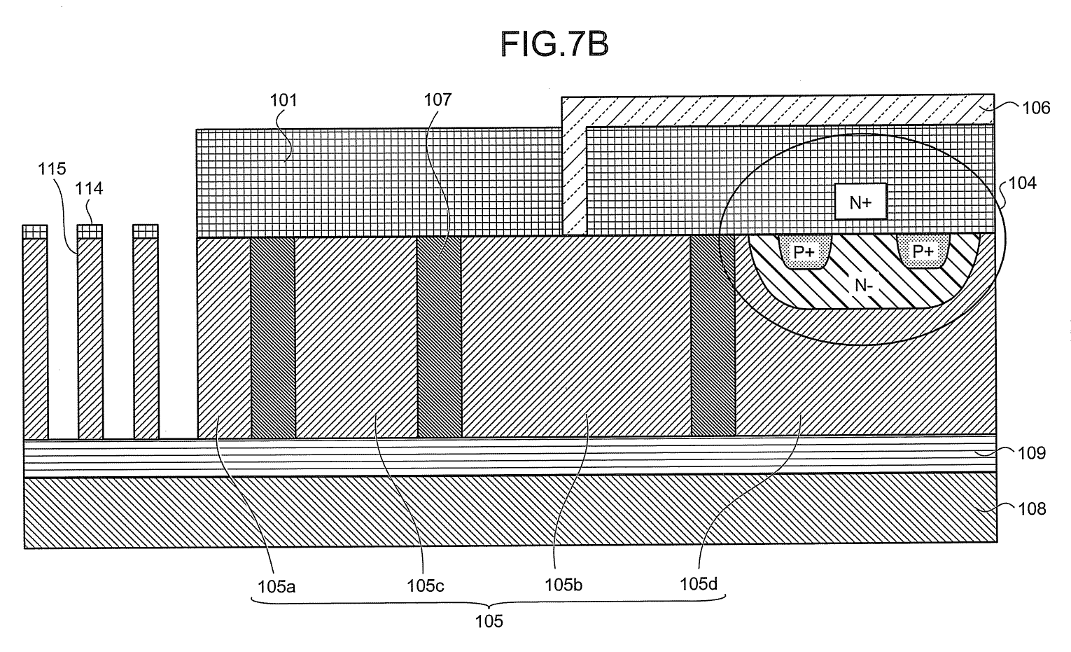

At step S4, all of the second mask layer 113 is removed, as shown in FIGS. 7A and 7B.

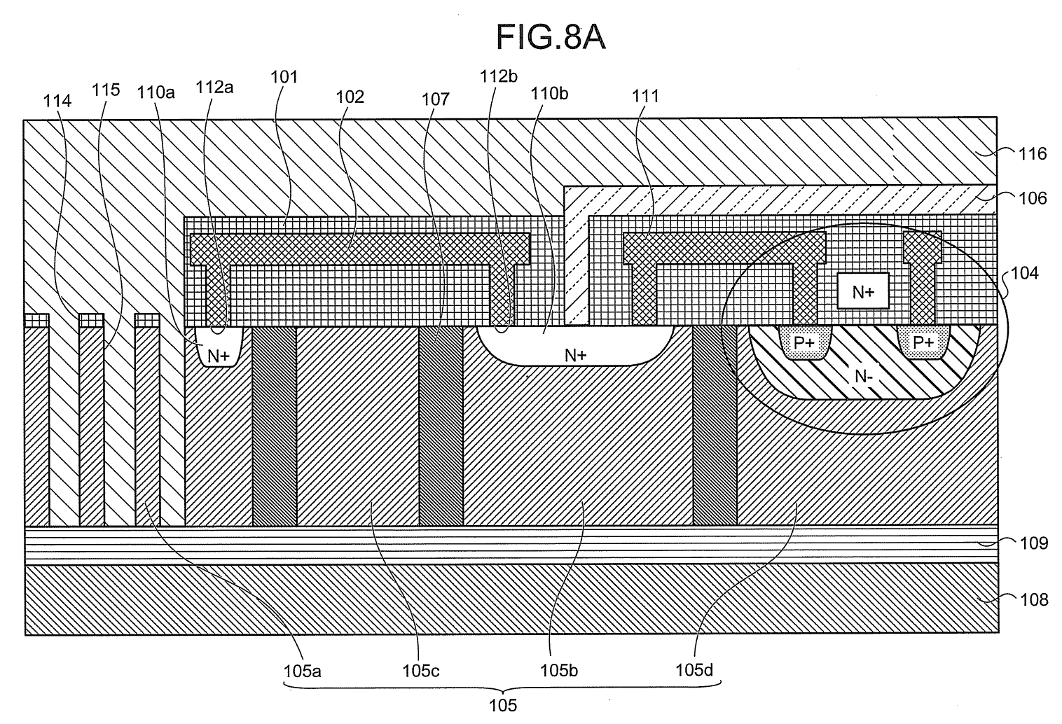

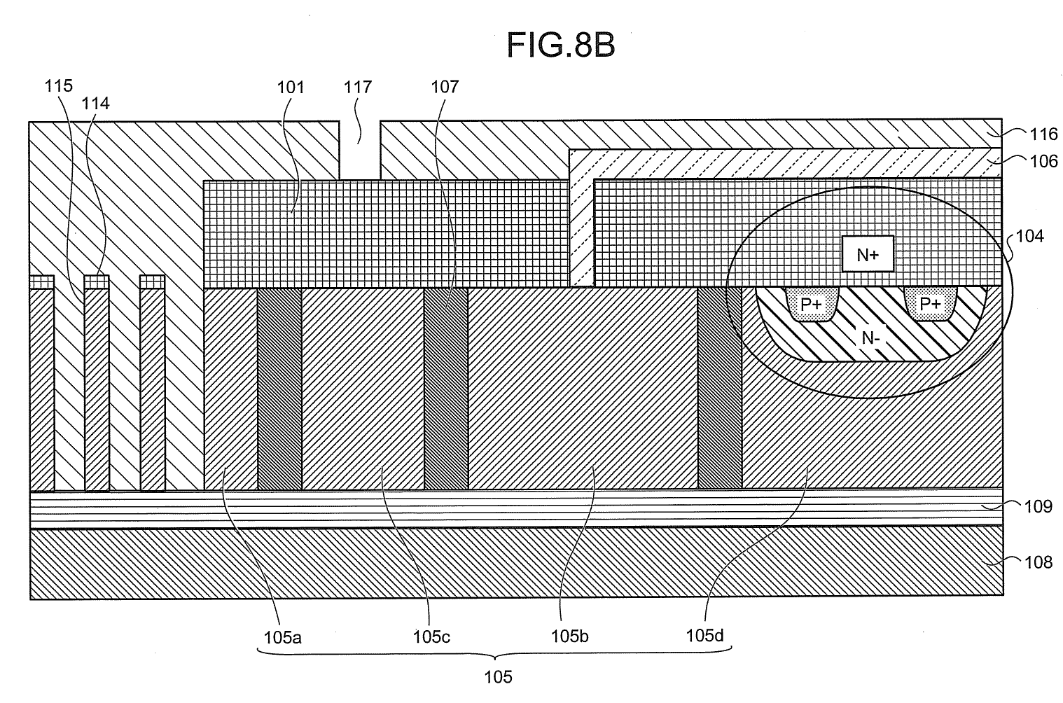

At step S5, a third mask layer 116 is formed on top of the insulation layer 101 (including the unetched portion 114) and the first mask layer 106, as shown in FIGS. 8A and 8B. A photoresist is used on the third mask layer 116. As portion around the unetched portion 115 of the first element layer 105a has been removed by the second etching process, a considerably thick photoresist needs to be coated to pack the etched out portion. The third mask layer 116 is formed by applying, exposing, and developing the photoresist.

The third mask layer 116 is formed covering the entire surface of the substrate in the region in FIG. 8A corresponding to the viewline A-A of FIG. 1. As compared to this, in the region in FIG. 8B corresponding to the viewline B-B of FIG. 1, the resist window 117 shown in FIG. 1 is formed in the third mask layer 116. The insulation layer 101 lies immediately below the resist window 117, and the third element layer 105c completely surrounded by the insulation trenches 107 lie below the insulation layer 101.

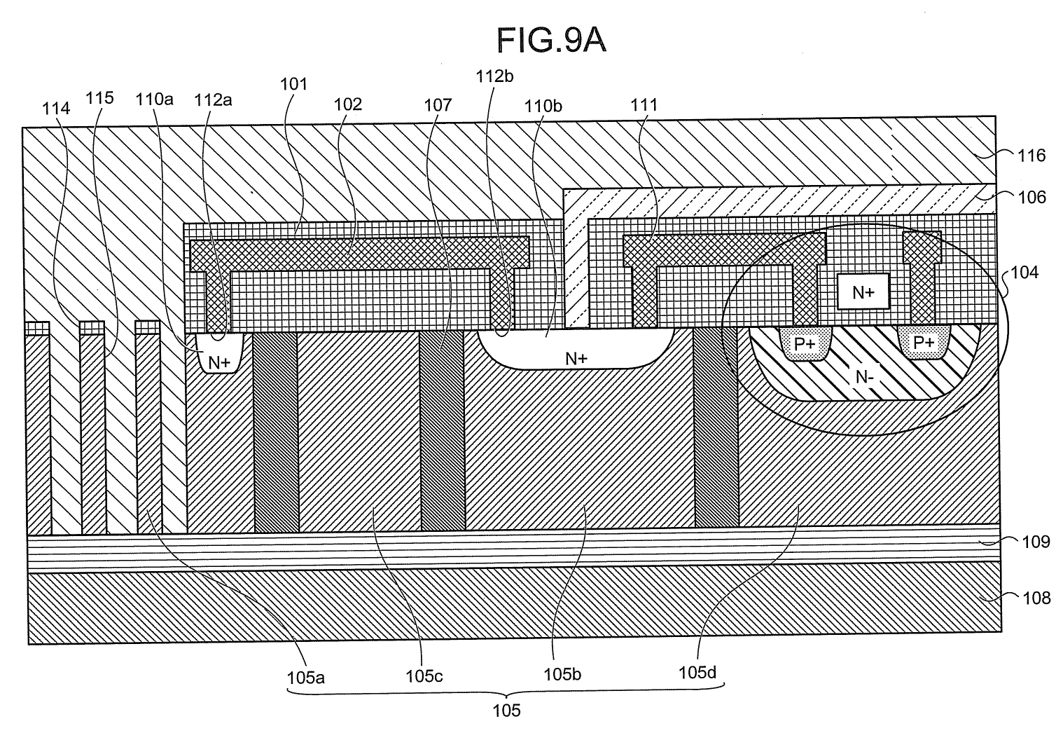

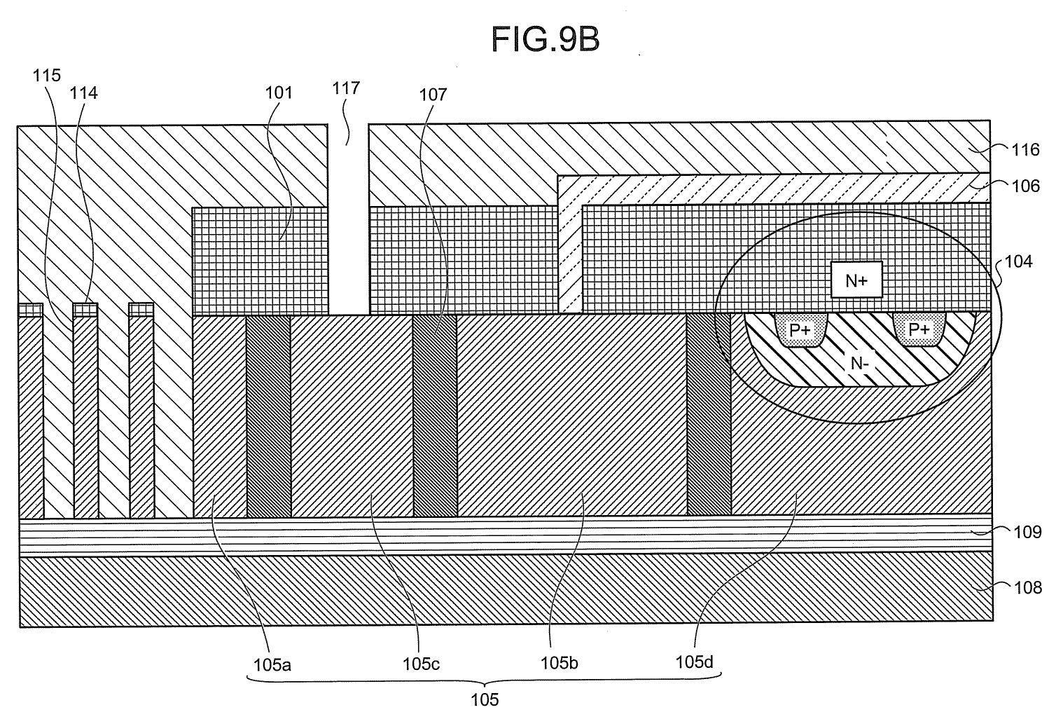

At step S6, the insulation layer 101 below the resist window is removed by anisotropic etching, as shown in FIGS. 9A and 9B. Anisotropic etching is performed by reactive ion etching or deep reactive ion etching. As there is no resist window 117 in the region in FIG. 9A corresponding to the viewline A-A of FIG. 1, the insulation layer 101 left intact. As compared to this, the insulation layer 101 lying below the resist window 117 in the region in FIG. 9B corresponding to the viewline B-B of FIG. 1 is removed by this etching process. It implies that this etching process does not in any way affect the first thin conductive layer 102 that is slotted to form a portion of the MEMS element.

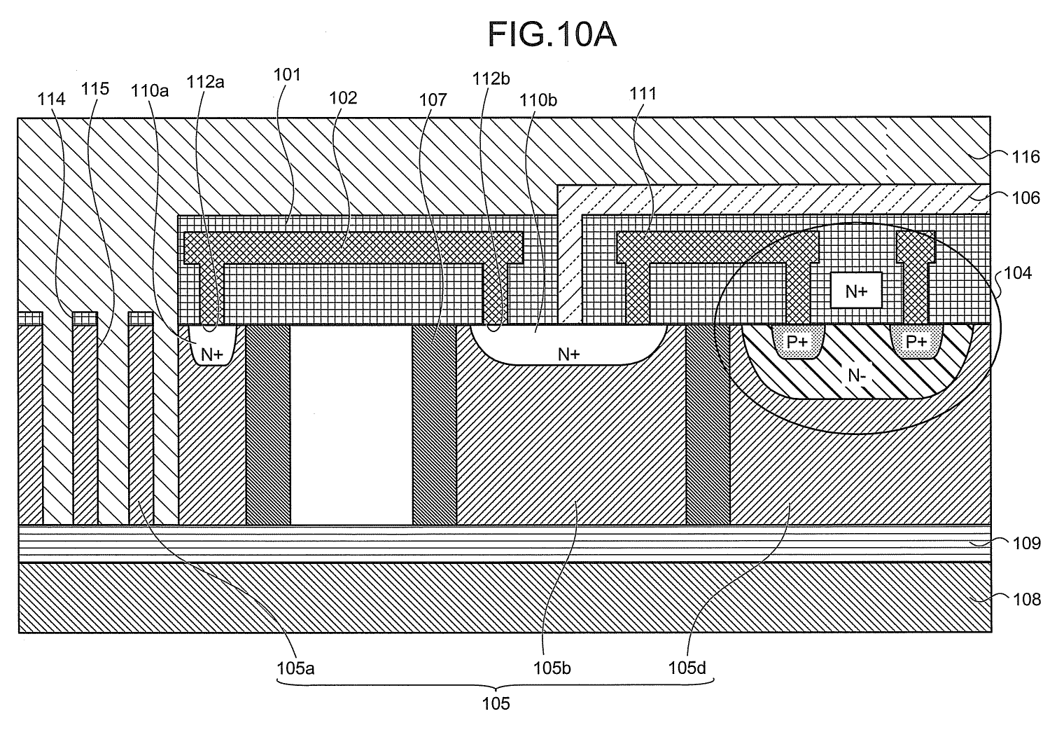

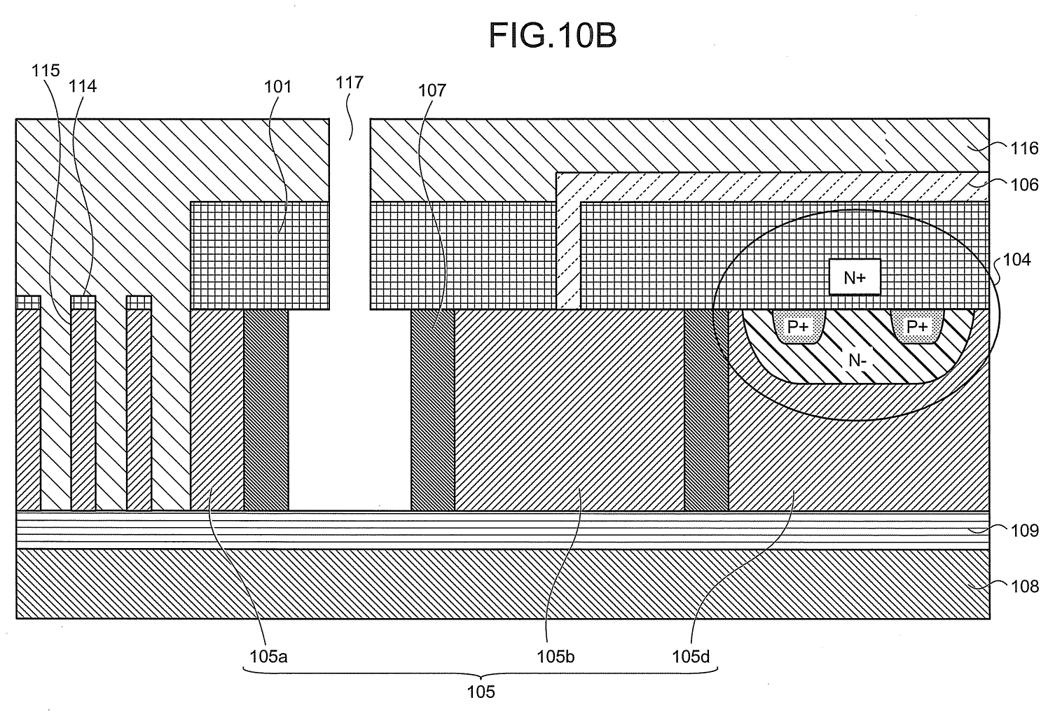

At step S7, the third element layer 105c below the first thin conductive layer (beams) 102 is removed by etching (second removal process), as shown in FIGS. 10A and 10B. The third element layer 105c is etched by anisotropic etching. Xenon difluoride (XeF2), which has a fast etching period and is highly selective to silicon, is used for etching.

It is noted that the third element layer 105c is completely surrounded by the insulation layer 101, the insulation trenches 107, and the buried silicon oxide (BOX) layer 109. The boundary formed by the insulation layer 101, the insulation trenches 107, and the buried silicon oxide (BOX) layer 109 serves as a barrier to etching, obviating the need for time-locked etching. The third element layer 105c within the boundary is completely removed during this etching process. The first thin conductive layer 102 that will form a part of the MEMS element is in no way affected by this etching process.

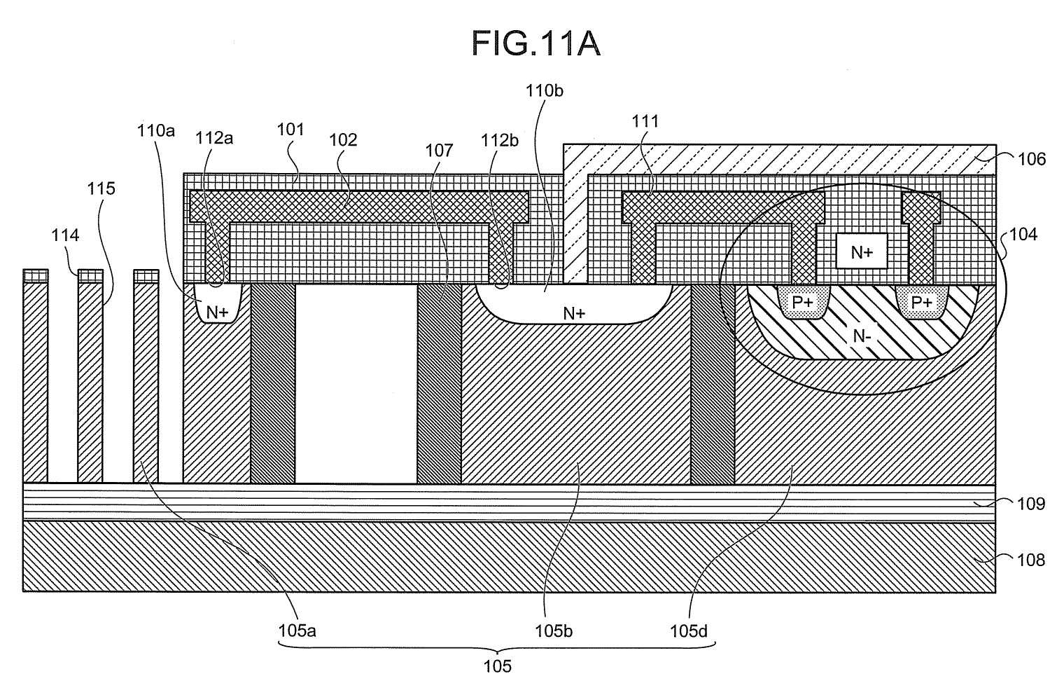

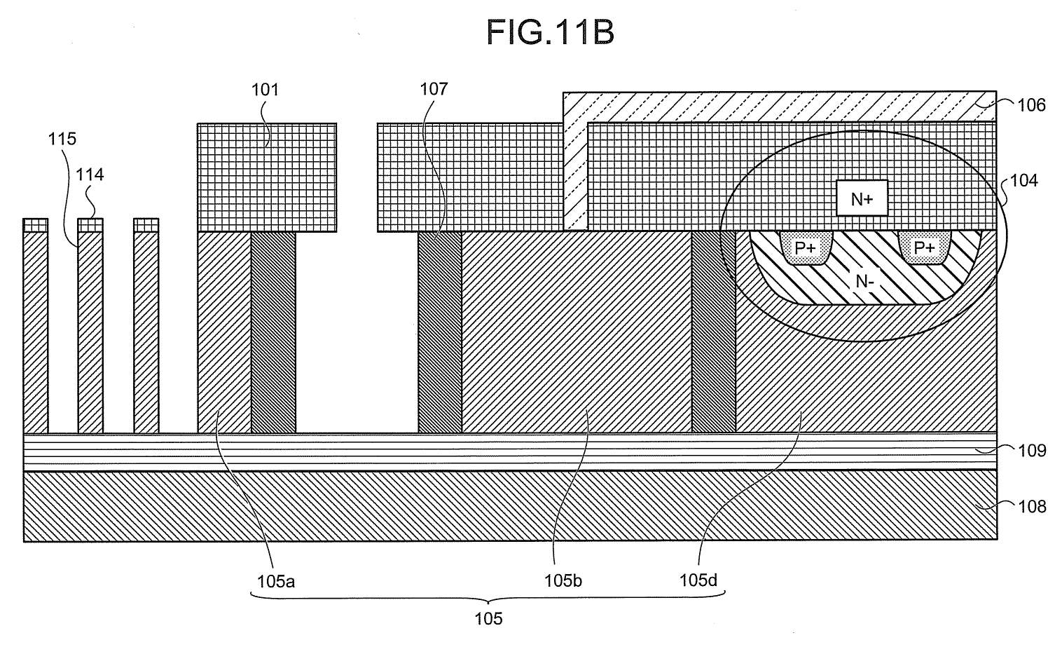

At step S8, the third mask layer 116 is removed, as shown in FIGS. 11A and 11B.

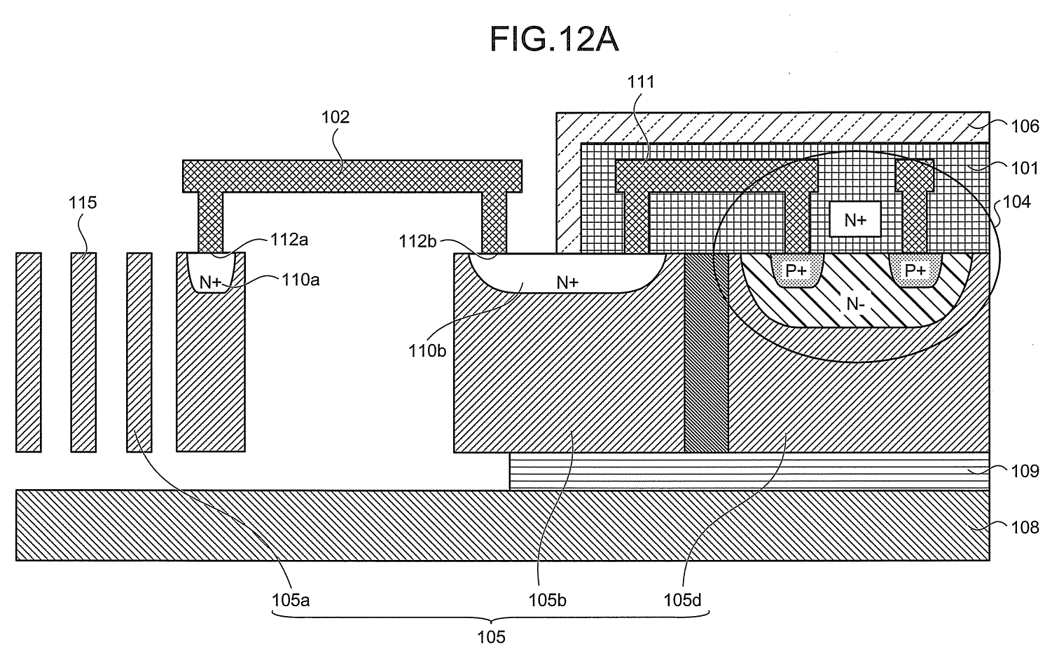

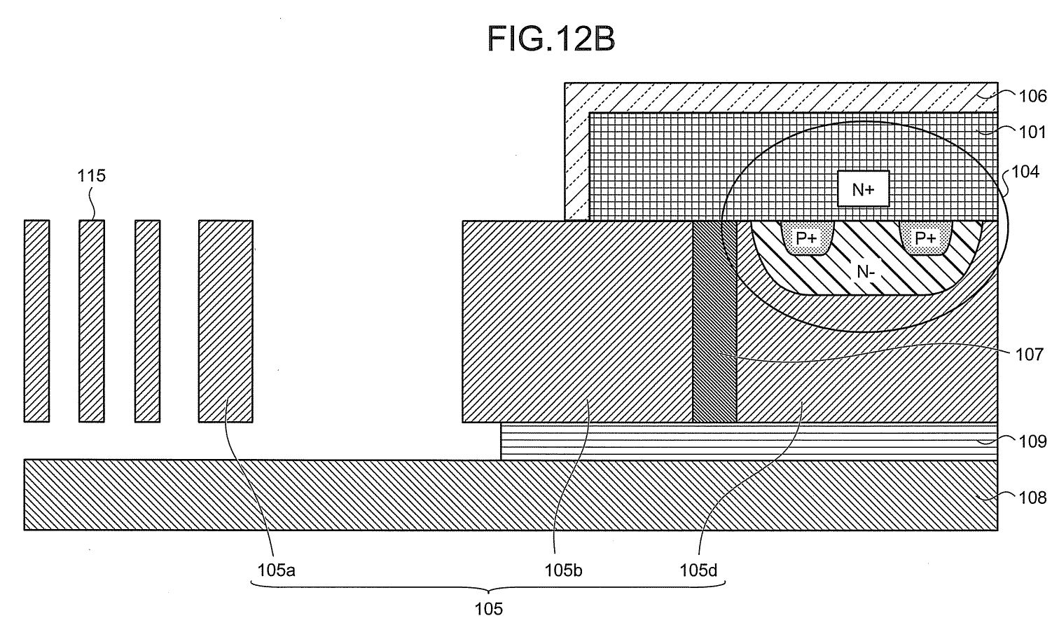

At step S9, the insulation layer 101, the insulation trenches 107, and the buried silicon oxide (BOX) layer 109 that are holding the structural components of the MEMS element are removed by release etching (third removal process), as shown in FIGS. 12A and 12B.

Release etching is performed with 50% hydrofluoric acid (HF), which is highly selective to silicon dioxide. Therefore, the first element layer 105a (including the unetched portion 115), and the substrate 108, which are made of silicon, are not affected in anyway by the release etching process. The silicon substrate wafer is further subjected to super-critical drying. Alternatively, instead of subjecting the wafer to wet etching and super-critical drying, release etching can be simply carried out by confining the wafer to a room filled with HF vapor.

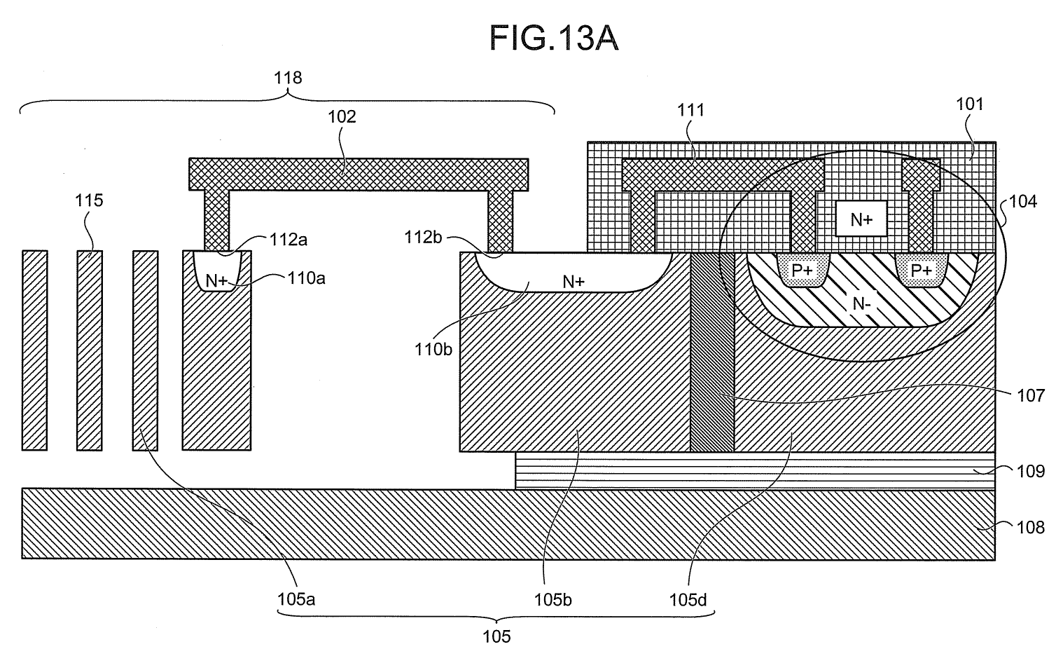

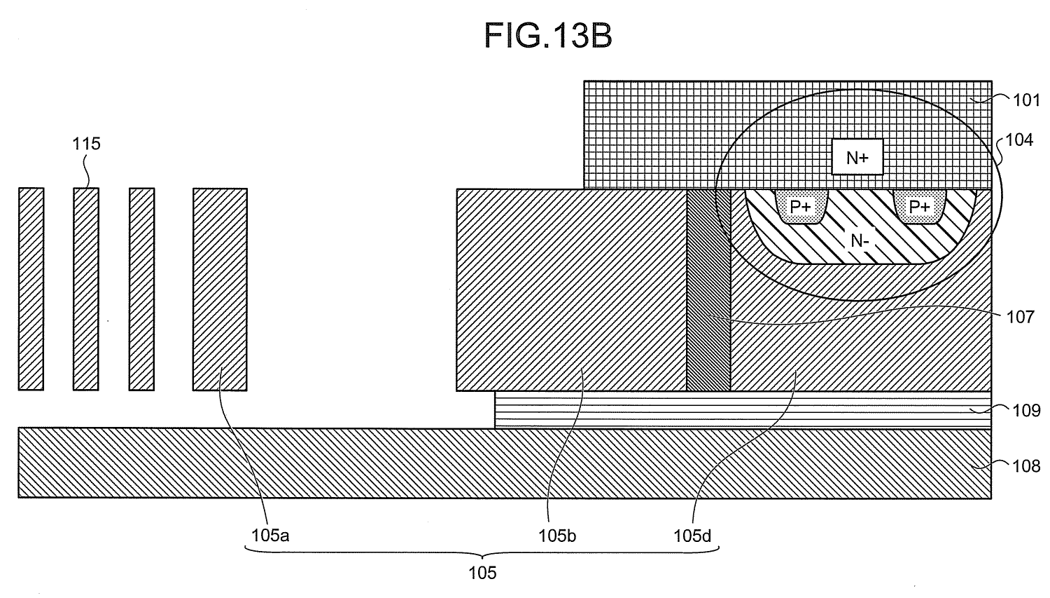

At step S10, if the first mask layer 106 covering the entire CMOS circuit 104 is present, the first mask layer 106 is removed, as shown in FIGS. 13A and 13B. Finally, both MEMS element 118 and the CMOS circuit 104 are formed on the same substrate 108.

Thus, the formation of the MEMS element 118 is completed from steps S1 to S10. The MEMS element 118 includes the first thin conductive layer 102 that forms the metallic beams, the unetched portion 115 of the first element layer 105a, a portion of the second element layer 105b, the first N-type region 110a, and a portion of the second N-type region 110b. The unetched portion 115 of the first element layer 105a is separated from the substrate 108. Especially, a part of the unetched portion 115 of the first element layer 105a is connected to the first thin conductive layer 102 through the first N-type region 110a at the first contact portion 112a. The first thin conductive layer 102 that forms the metallic beams is connected to the second element layer 105b through and the second N-type region 110b at the second contact portion 112b. There is no silicon layer between the first thin conductive layer 102 and the substrate 108. It is assumed that a portion of the first element layer 105a connected to the first thin conductive layer 102 not shown in FIG. 1 is removed (by the second etching process), forming an island-like structure on the buried silicon oxide (BOX) layer 109. In this case, the unetched portion 115 of the first element layer 105a floats over the substrate 108 after completion of the process at step S10. The first thin conductive layer 102 and the unetched portion 115 of the first element layer 105a connected to the first thin conductive layer 102 can freely move about the second contact portion 112b, which serves as a fulcrum.

The manufacturing method required for manufacturing the three-dimensional MEMS is described above. However, it might be sufficient to represent an actual design or further development of the three-dimensional structure from the above description. Therefore, an actual application of three-dimensional MEMS fabrication method is described below with reference to examples of a pin hinge and a torsional hinge. These are just examples of a vast variety of MEMS structures that can be fabricated using the fabrication method described in the embodiment.

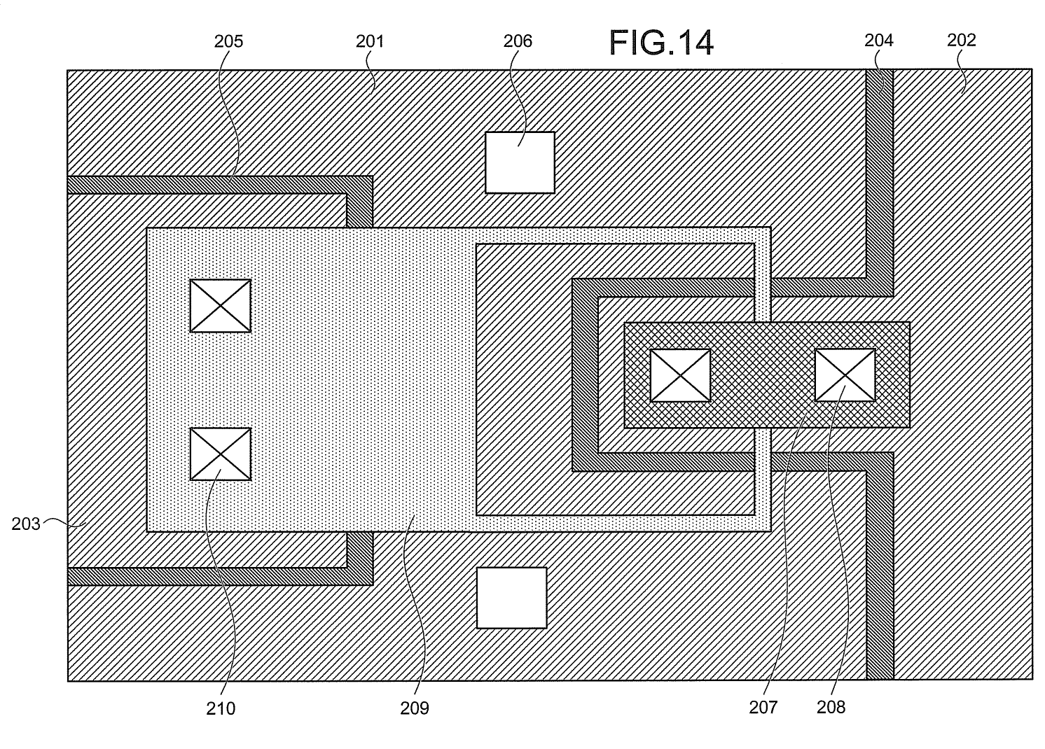

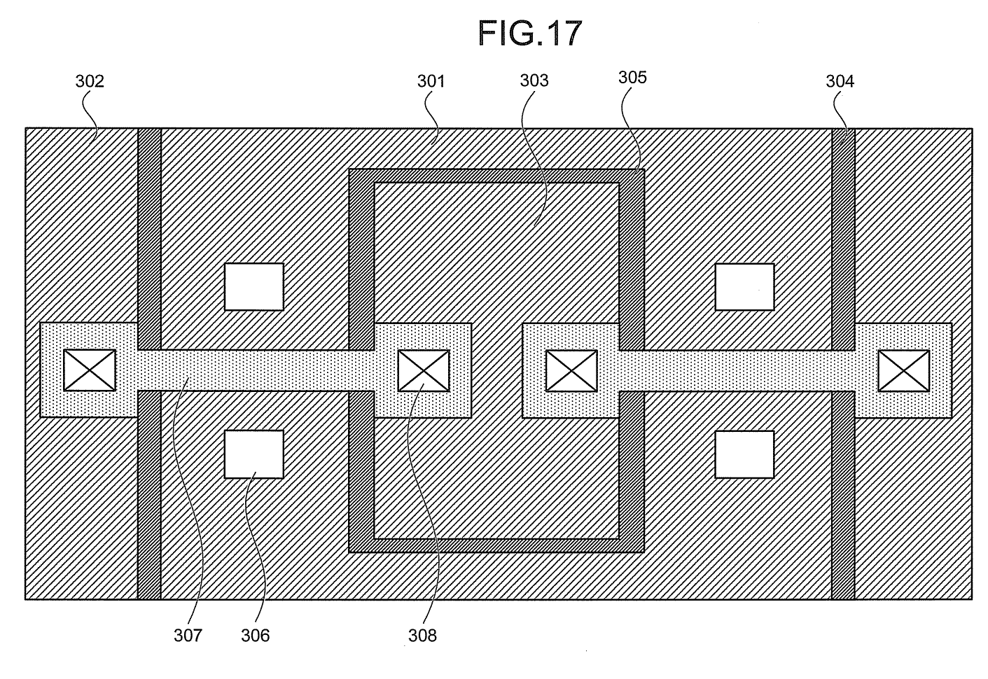

FIGS. 14 to 16 are drawings for explaining designing of a pin hinge as a MEMS element based on the wafer processing described with reference to FIGS. 1 to 13B. FIG. 17 to 19 are drawings for explaining designing of a torsional hinge as a MEMS element based on the wafer processing described with reference to FIG. 1 to 13B. The structures and processes in the FIGS. 14 to 19 that are identical to those described in FIGS. 1 to 13B are assigned identical reference numerals. The designing of the pin hinge is described first. FIG. 14 is a schematic view showing a circuit design of a pin hinge after the CMOS process and the MEMS process.

The pin hinge according to the embodiment is fabricated by the MEMS element fabrication method described above. An element layer 201 corresponds to the third element layer 105c, and is completely removed during a fourth etching process. An element layer 202 represents an element level substrate connected to the right side of the hinge. An element layer 203 represents an element level substrate connected to the left side of the hinge. The element layers 202 and 203 correspond to the first element layer 105a, the second element layer 105b, or the fourth element layer 105d. An insulation trench 204 separates the element layers 201 and 202. Another insulation trench 205 separates the element layers 201 and 203. The insulation trenches 204 and 205 correspond to the insulation trenches 107.

Windows 206 opens into the resist window 117 of the third mask layer 116 and the insulation layer 101 disposed below the resist window 117. A thin metallic layer 207 corresponds to the first thin conductive layer 102 and is fixed to the element layer 202 by a contact portion 208 during the CMOS process. A polysilicon gate layer 209 is a polysilicon gate in the CMOS process, and is fixed to the element layer 203 by a contact portion 210 during the CMOS process.

XeF2 is injected into the windows 206 in the fourth etching process. As a result, the element layer 201 is completely removed by the XeF2. However, the element layers 202 and 203 are not affected because of the insulation trenches 204 and 205. The insulation trenches 204 and 205 are completely removed by HF in the release etching process.

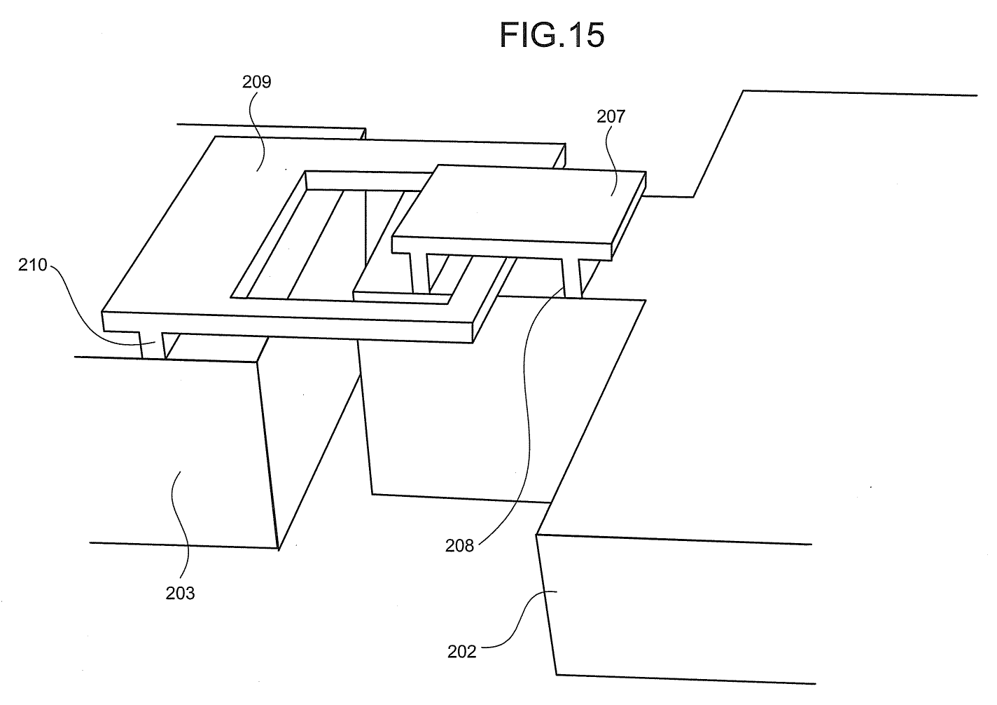

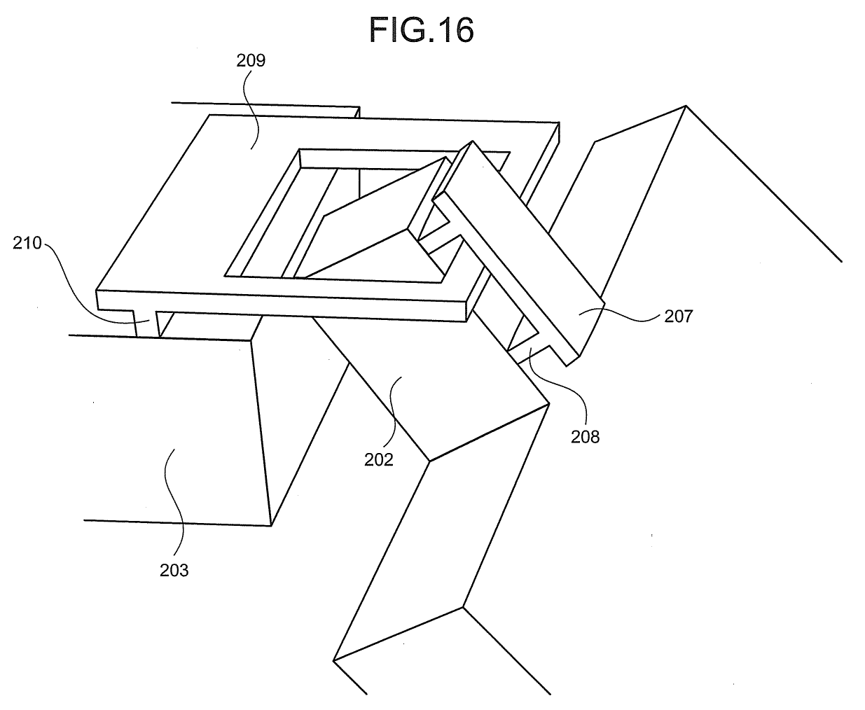

FIG. 15 is a schematic view showing the pin hinge in its finished form. The element layer 201, the insulation trenches 204 and 205, and the insulation trench 107 surrounding the thin metallic layer 207 and the polysilicon gate layer 209 are removed. The element layer 202, the thin metallic layer 207, and the contact portion 208 form the right side of the hinge. The element layer 203, the polysilicon gate layer 209, and the contact portion 210 form the left side of the hinge. FIG. 16 is a schematic view showing the hinge to explain its movement in an easily understood manner. This structure is only one of a large number of possible structures that illustrate the usefulness of the fabrication method to fabricate such out-of-plane structures.

Designing the torsional hinge is explained below. The pin hinge uses a rotating piece that rotates about a shaft. On the other hand, long beams are used in the torsional hinge that contribute to a twisted rotation.

FIG. 17 is a schematic view showing a circuit design of the torsional hinge after the CMOS process and the MEMS process. The torsional hinge according to the embodiment is fabricated by the MEMS element fabrication method described above. An element layer 301 corresponds to the third element layer 105c is completely removed by the fourth etching process. An element layer 302 represents an element level substrate connected to the left side and the right side of the hinge, and corresponds to the first element layer 105a, the second element layer 105b, or the fourth element layer 105d. An element layer 303 represents an element level substrate connected to the central portion of the hinge, and corresponds to the first element layer 105a, the second element layer 105b, or the fourth element layer 105d.

An insulation trench 304 separates the element layers 301 and 302. An insulation trench 305 separates the element layers 301 and 303. The insulation trenches 304 and 305 correspond to the insulation trenches 107. Windows 306 open into the resist window of the third mask layer 116 and the insulation layer blow the resist window 117. A thin metallic layer 307 corresponds to the first thin conductive layer 102 and is fixed to the element layers 302 and 303 by a contact portion 308 during the CMOS process.

XeF2 is injected into the windows 306 in the fourth etching process. As a result, the element layer 301 is completely removed by the XeF2. However, the element layers 302 and 303 are not affected because of the insulation trenches 304 and 305. The insulation trenches 304 and 305 are completely removed by HF in the release etching process.

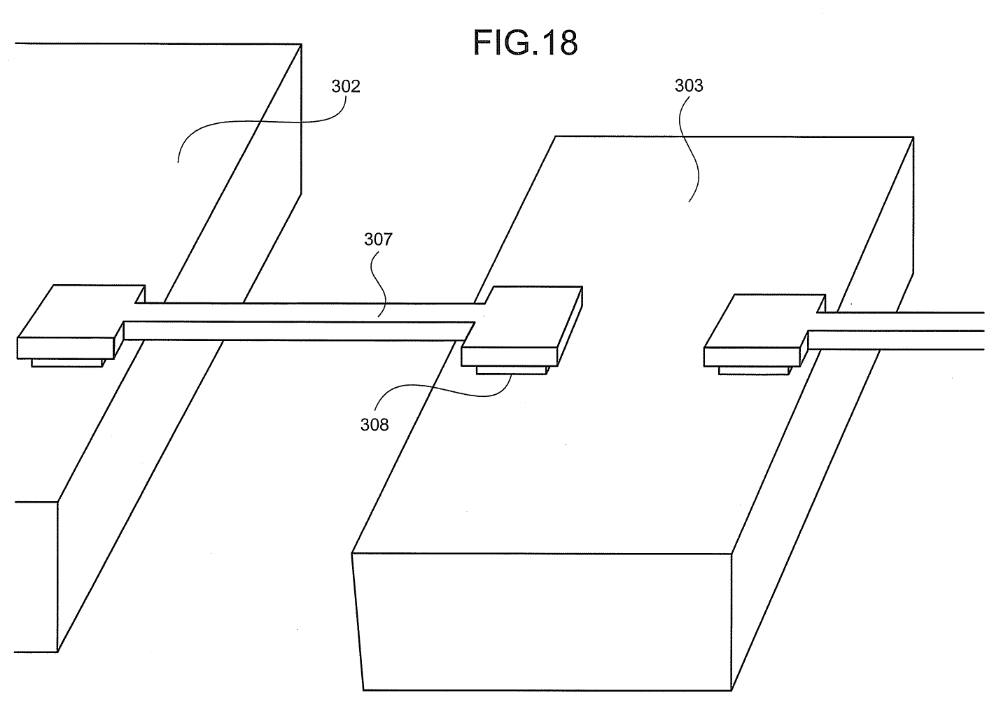

FIG. 18 is a schematic view showing the torsional hinge in its finished form. The insulation layer 101 that surrounds element layer 301, the insulation trenches 304 and 305, and the thin metallic layer 307 is removed. The element layers 302 and 303, the thin metallic layer 307, and the contact portion 308 form the torsional hinge. The element layer 303 that forms the central portion of the hinge is separated from the element layer 302 that forms the two sides of the hinge, and supported only by the thin metallic layer 307 forming the beams of the hinge. In the present example, a metal is used as the material of the portion that forms the beams of the hinge. Alternatively, polysilicon gate can also be used.

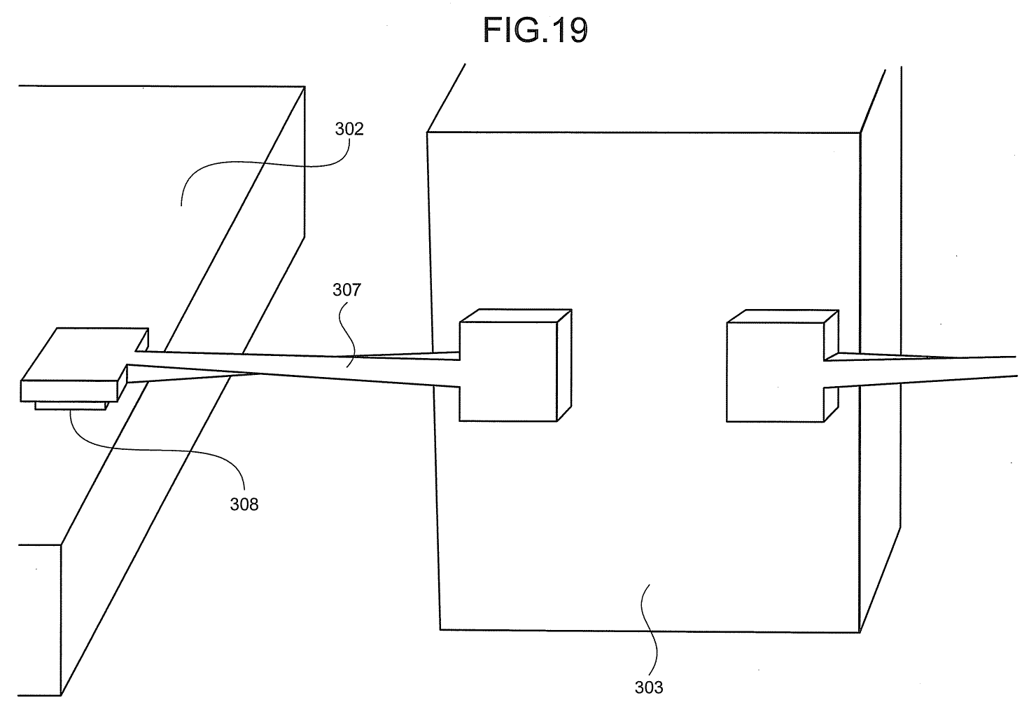

In FIG. 18, the two ends of the hinge are level with the central portion of the hinge as there is no bias applied to the torsional hinge. FIG. 19 is a schematic view showing the torsional hinge to explain its movement in an easily understood manner when a bias is applied. As the thin metallic layer 307 is flexible, it can twist easily, enabling the hinge to swing. This structure is only one of a large number of possible structures that illustrate the usefulness of the fabrication method to fabricate such out-of-plane structures.

According to the embodiment, a thick mechanical layer can be made to display a large actuation area by enabling mechanical actuation of conductive beams and a portion of an element layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of fabricating a MEMS element comprising:
forming a MEMS element by forming a circuit layer on an element layer of an SOI substrate that is formed by laminating on a substrate, a first insulation layer and the element layer, and forming a second insulation layer including a conductive beam electrically connected to the circuit layer on the element layer on which the circuit layer is not formed;
first removing a part of the second insulation layer and a part of the element layer by anisotropic etching;
second removing by forming an opening reaching to the element layer in the second insulation layer, and removing the element layer located below the conductive beam through the opening by isotropic etching; and
third removing by removing the second insulation layer to expose the conductive beam, and removing the first insulation layer located below the conductive beam.

2. The method according to claim 1, wherein the element layer surrounded by a barrier constituting a part of the second insulation layer and the first insulation layer other than the barrier is removed in the second removing.

3. The method according to claim 1, wherein the element layer located below the conductive beam is removed by XeF2 etching in the second removing.

4. The method according to claim 1, wherein an unremoved portion of the second insulation layer in the first removing serves as an etching mask for the element layer.

5. The method according to claim 1, wherein a part of the element layer is removed by reactive ion etching in the first removing.

6. The method according to claim 5, wherein a part of the element layer is removed by deep reactive ion etching in the first removing.

7. The method according to claim 1, wherein at least one of the second insulation layer around the conductive beam and a part of the first insulation layer remained in the first removing is removed by HF etching in the third removing.

8. A MEMS element comprising:
a substrate;
a first element layer including a circuit layer and a second element layer formed on the substrate; and
a conductive beam that connects the first element layer and the second element layer, wherein
the conductive beam and the second element layer are separated from the substrate and are capable of mechanical actuation.

9. The element according to claim 8, wherein the conductive beam can be actuated as a torsional hinge or a pin hinge.

10. The element according to claim 8, wherein the conductive beam can be bent to form a right angle with respect to a surface of the substrate.

11. The element according to claim 8, wherein the conductive beam is formed of silicon or metal.
